(19) United States
(12) Patent Application Publication
(10) Pub. No.: US 2008/0295963 A1
(43) Pub. Date: Dec. 4, 2008

(54) Gas supply system and gas supply accumulation unit of semiconductor manufacturing apparatus

(75) Inventors: Shuji Moriya, Nirasaki-Shi (JP); Ken Nakao, Nirasaki-Shi (JP)

Correspondence Address: SMITH, GAMBRELL & RUSSELL, 1130 CONNECTICUT AVENUE, N.W., SUITE 1130, WASHINGTON, DC, 20036, US

(73) Assignee: Tokyo Electron Limited

(21) Appl. No.: 12/068,029

(22) Filed: Jan. 31, 2008

(30) Foreign Application Priority Data
Feb. 26, 2007 (JP) 2007-045973

(51) Int. Cl. C23F 1/08; C23C 16/00; C23C 14/34

(52) U.S. Cl. 156/345.24; 118/715; 118/712; 156/345.29; 204/298.01

(57) ABSTRACT

A gas supply system 200 is a system that supplies a predetermined gas from a gas supply source 210 to a processing part 110 of a semiconductor manufacturing apparatus 100. The gas supply system 200 includes a gas supply passage apparatus 220 that is connected to the gas supply source 210 and the processing part 110. The gas supply passage apparatus 220 is provided with a plurality of fluid controllers (a hand valve 231, a pressure reducing valve 232, a manometer 233, a check valve 234, a first shutoff valve 235, a second shutoff valve 236, a massflow controller 237, and a gas filter 238), and passage structuring members (passage blocks 241 to 249) that are connected to positions between the respective fluid controllers 231 to 238 and form gas passages 221 to 229. The passage structuring members are made of a carbon material. Thus, when a corrosive gas is supplied to the processing part 110, mixture of a metal contaminant into a substrate to be processed W can be prevented as much as possible.

### CROSS REFERENCE TO RELATED APPLICATIONS

This application is based upon and claims the benefit of priority from the prior Japanese Patent Application No. 2007-045973 filed on Feb. 26, 2007, the entire contents of which are incorporated herein by reference.

### FIELD OF THE INVENTION

The present invention relates to a gas supply system and a gas supply accumulation unit of a semiconductor manufacturing apparatus.

### BACKGROUND ART

A semiconductor manufacturing apparatus, such as a diffusion apparatus, an etching apparatus, and a sputtering apparatus, including a gas supply system for supplying a gas from a process-gas supply source, such as a gas cylinder, to a processing part. By conducting a step for manufacturing a semiconductor device with the use of a gas supplied from the gas supply system, e.g., by conducting a film-deposition step and an etching step with the use of a predetermined gas, a surface of an object to be processed, such as a semiconductor wafer, is processed.

In such a manufacturing step of a semiconductor wafer, a highly corrosive gas, such as a chlorine gas and silane gases, is used depending on the type of a process. Thus, various measures are taken for supplying a cleaner gas. For example, SUS 316L, which has relatively a larger corrosion resistance, is used as a gas piping material constituting a gas supply passage apparatus. As measures for preventing corrosion at a welding part of a gas piping through which chlorine gases and/or silane gases are circulated, a part or all the part of a gas passage is made of predetermined an austenite stainless steel, for example (see, JP5-68865A).

[Patent Document 1] JP5-68865A

### DISCLOSURE OF THE INVENTION

However, even when a stainless steel is used as a material of a gas piping constituting a gas supply passage apparatus, as described above, corrosion of the gas piping cannot be completely prevented depending on the kind of a corrosive gas. Namely, there have been problems in that a corrosive gas reacts with a metal constituting the gas piping so that an undesired metal compound is generated, and that the gas piping is corroded whereby a metal component (Fe, Cr, Ni, or the like) constituting the gas piping comes to be mixed into the corrosive gas. In particular, since fluorinated corrosive gases (e.g., HF gas, F₂ gas, CIF₃ gas, or the like) are highly corrosive, corrosion of a gas piping cannot be absolutely avoided even when the gas piping is made of a stainless steel. In addition, metal components come to be mixed into the corrosive gas, and the corrosive gas reacts with the metal constituting the gas piping so that an undesired metal component (metal fluoride) is generated.

Together with the corrosive gas, the thus generated metal component and metal compound generated in the gas supply passage apparatus penetrate the semiconductor manufacturing apparatus to thereby invite a problem of metal contamination such as generation of particles.

Particularly, because of the recent higher degree of integration and higher performance of a semiconductor device, even a slight metal contamination causes a considerable damage to a throughput, a quality, and a reliability of products. Causes of defective devices by the metal contamination are, for example, an impaired pattern caused by a particulate metal contaminant (particle), and deterioration in electric property caused by an atomic or molecular contaminant such as a heavy metal contaminant.

The present invention has been made in view of the above circumstances. The object of the present invention is to provide a gas supply system and a gas supply accumulation unit of a semiconductor manufacturing apparatus, which are capable of preventing mixture of a metal contaminant into an object to be processed as much as possible.

Means for Solving the Problem

In order to achieve the above object, according to the present invention, there is provided a gas supply system of a semiconductor manufacturing apparatus, for supplying a predetermined gas from a gas supply source to a processing part of the semiconductor manufacturing apparatus, the gas supply system comprising a gas supply passage apparatus that is connected to the gas supply source and the processing part, wherein the gas supply passage apparatus includes: a plurality of fluid controllers; and a passage structuring member including a passage, the passage structuring member connecting the respective fluid controllers; and the passage structuring member is made of a carbon material.

According to the present invention, the respective passage structuring members for connecting the fluid controllers are made of a carbon material which is a nonmetallic material. Thus, even when a highly corrosive gas is circulated through the passages of the passage structuring members, generation of a metal contaminant in the passages can be prevented, while mixture of metal components caused by corrosion can be prevented. Therefore, mixture of a metal contaminant into an object to be processed can be prevented as much as possible.

In addition, the passage structuring member is formed of a passage block including a passage. By making the respective passage blocks themselves constituting the passages out of a nonmetallic carbon material, mixture of a metal contaminant into an object to be processed can be prevented as much as possible. Additionally, a degree of accumulation of the gas supply passage apparatuses can be made higher, while a strength of the parts constituting the passages can be made stronger, as compared with a case in which passages are formed of gas pipings.

In addition, the carbon material of the passage structuring member is formed of a carbon sintered material, a hard carbon material, or a combination thereof. Of these materials, it is preferable that the carbon sintered material is impregnated with a fluorocarbon resin. A porous carbon sintered compact impregnated with a resin such as a fluorocarbon resin can improve a gas leaking property.

The plurality of fluid controllers include a valve, a pressure reducing valve, and a manometer. In this case, it is preferable that each of the fluid controllers has a gas-contacting part which is in contact with the gas, and that the gas-contacting part is made of a carbon material. Thus, also in the fluid controllers, generation of a metal compound and mixture of a metal component can be prevented.

In order to achieve the above object, according to another aspect of the present invention, there is provided a gas supply accumulation unit for supplying a predetermined corrosive gas to a processing part of a semiconductor manufacturing apparatus, the gas supply accumulation unit comprising: a plurality of fluid controllers; and a passage block including a passage, the passage block connecting the respective fluid controllers; wherein the passage block is made of a carbon material.

According to the present invention, only the passage blocks in the gas supply accumulation unit using a corrosive gas which corrodes a metal of the members constituting the passages can be made of a carbon material. Further, the corrosive gas is formed of a fluorinated corrosive gas, for example. The corrosive gas is formed of an HF gas, an F₂ gas, a CIF₃ gas, or a mixture gas containing these gases, for example. Furthermore, it is preferable that the carbon material of the passage block is formed of a carbon sintered material impregnated with a fluorocarbon resin.

According to the present invention, when a corrosive gas is supplied to a processing part of a semiconductor manufacturing apparatus, mixture of a metal contaminant into an object to be processed can be prevented as much as possible.

### BRIEF DESCRIPTION OF THE DRAWINGS

FIG. 1 is a view of a structural example of a heat processing apparatus according to an embodiment of the present invention;

FIG. 2 is a view of a schematic appearance of a gas supply accumulation unit;

FIG. 3 is a sectional view of an example of an inner structure of a passage block to be located on the most upstream side position of the gas supply accumulation unit shown in FIG. 2;

FIG. 4 is a sectional view of an example of an inner structure of a passage block to be located on the most downstream side position of the gas supply accumulation unit shown in FIG. 2;

FIG. 5 is a sectional view of an example of an inner structure of each of the passage blocks to be located on intermediate positions of the gas supply accumulation unit shown in FIG. 2;

FIG. 6 is a sectional view of another structural example of each of the passage blocks to be located on intermediate positions of the gas supply accumulation unit shown in FIG. 2; and

FIG. 7 is a sectional view of another structural example of each of the passage blocks to be located on intermediate positions of the gas supply accumulation unit shown in FIG. 2.

### BEST MODE FOR CARRYING OUT THE INVENTION

A preferred embodiment of the present invention is described in detail below with reference to the accompanying drawings. In the present specification and drawings, the same parts having substantially the same function and structure are shown by the same reference numbers, and an overlapped description thereof is omitted.

(Structural Example of Semiconductor Manufacturing Apparatus)

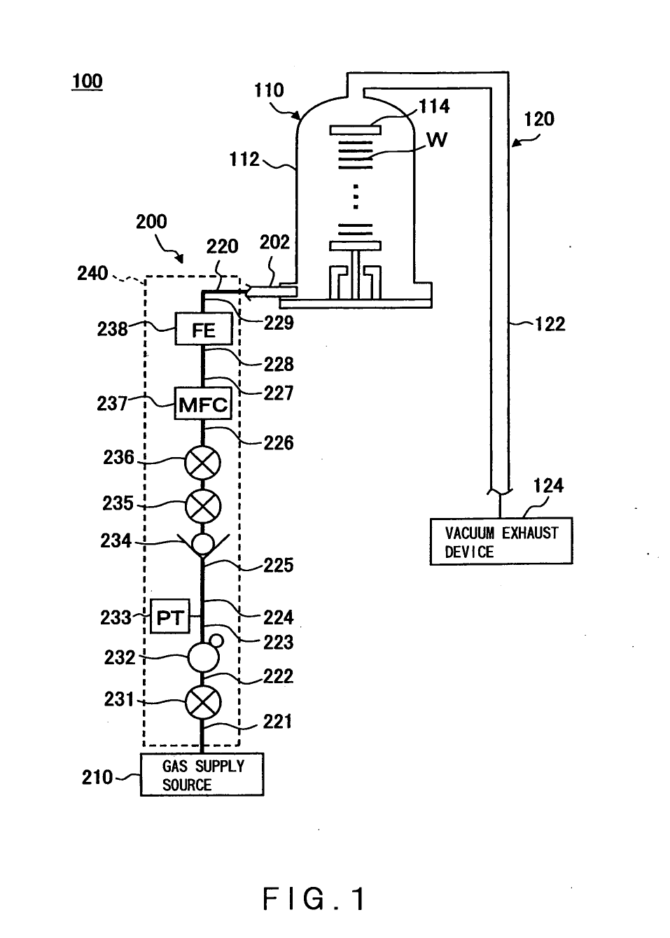

At first, an embodiment in which a gas supply system according to the present invention is applied to a semiconductor manufacturing apparatus is described with reference to the drawings. Given herein as an example to describe the semiconductor manufacturing apparatus is a heat processing apparatus that subjects a predetermined heat process to a substrate such as a semiconductor wafer (hereinafter also referred to simply as “wafer”). FIG. 1 is a view of a structural example of a heat processing apparatus according to the present invention.

A heat processing apparatus 100 includes a heat processing part 110 which is a processing part for processing (e.g., thermally processing) a wafer W. As shown in FIG. 1, the heat processing part 110 has, e.g., a vertical reaction tube 112 constituting a reaction vessel (processing vessel) or a reaction chamber (processing chamber). A holder 114 holding a plurality of wafers W can be loaded into the reaction tube 112. Connected to the heat processing part 110 are an exhaust system 120 that evacuates the reaction tube 112, a gas supply system 200 which is an example of a gas supply system of this embodiment that supplies a predetermined process gas into the reaction tube 112, and a heating device (e.g., heater), not shown, disposed outside of the reaction tube 112.

The heat processing part 110 subjects a predetermined heat process to a wafer W. In this case, the holder 114 holding a plurality of wafers W is firstly loaded into the reaction tube 112 of the heat processing part 110. Then, a predetermined gas is supplied by the gas supply system 200 into the reaction tube 112 in which the holder 114 is accommodated, and the reaction tube 112 is heated from outside by the heating device, with the reaction tube 112 being evacuated by the exhaust system 120. In this manner, the wafers W are subjected to a predetermined heat process.

The exhaust system 120 includes a vacuum exhaust device 124 structured by, e.g., a vacuum pump, and an exhaust pipe 122 which has one end thereof connected to the vacuum exhaust device 124 and the other end thereof connected to a ceiling of the reaction tube 112. Although illustration is omitted in FIG. 1, the exhaust pipe 122 of the exhaust system 120 is detoured and connected to the gas supply system 200 by a bypass line. The bypass line is connected to a gas supply passage apparatus 220 at an upstream position thereof by via bypass pipe. An exhaust side bypass shutoff valve is connected to the bypass pipe at a position near the exhaust system, while a supply side bypass shutoff valve is connected to the bypass pipe at a position near the gas supply system 200.

(Structural Example of Gas Supply System)

Next, the gas supply system 200, which is an example of the gas supply system of this embodiment, is described. The gas supply system 200 includes a gas supply source 210 formed of a cylinder which is filled with a fluorinated corrosive gas such as HF, F₂ gas, CIF₃, or the like. The corrosive gas can be used as a process gas for processing a wafer W, or as a cleaning gas, for example. One end of the gas supply passage apparatus 220 is connected to the gas supply source 210, while the other end of the gas supply passage apparatus 220 is connected to a nozzle (e.g., injector) 202 for introducing the gas into the reaction tube 112. Thus, the gas can be supplied from the gas supply source 210 into the reaction tube 112 through the gas supply passage apparatus 220.

The gas supply passage apparatus 220 is provided with a plurality of fluid controllers. In this embodiment, there are provided, as such fluid controllers, a hand valve 231, a pressure reducing valve (regulator) 232, a pressure gage (PT) 233, a check valve 234, a first shutoff valve (valve) 235, a second shutoff valve (valve) 236, a massflow controller (MFC) 237, and a gas filter (FE) 238, in this order from the upstream side of the gas supply passage apparatus 220 shown in FIG. 1. To intermediate positions of the respective fluid controllers 231 to 238, there are connected passage structuring members (passage blocks 241 to 249) in which gas passages 221 to 229 are formed, respectively.

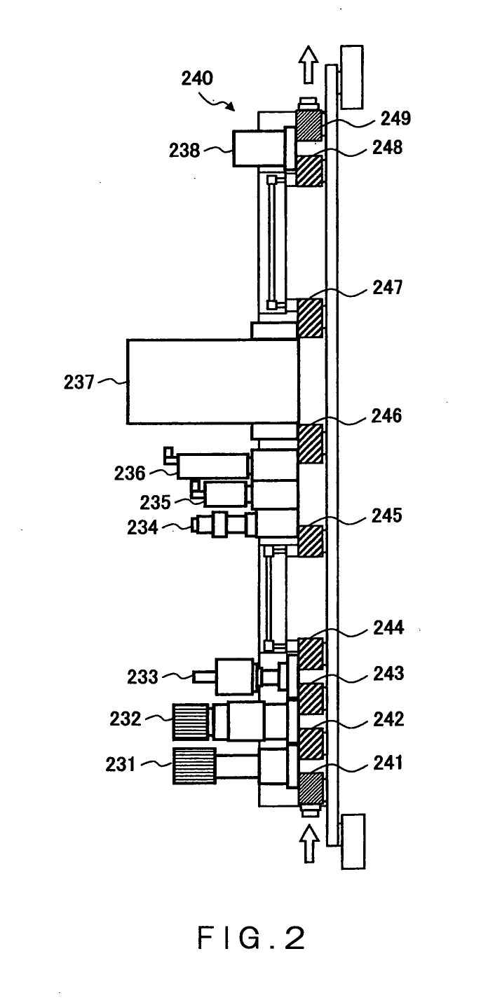

A concrete structural example of this gas supply passage apparatus 220 is described with reference to the drawings. Herein, there is taken as an example a gas supply accumulation unit which is structured by passage blocks connecting the gas supply passage apparatus 220 to the respective fluid controllers. By structuring the gas supply passage apparatus 220 with the use of the gas supply accumulation unit, the respective controllers can be accumulated and the gas supply passage apparatus 220 can be made smaller. FIG. 2 is a view of a schematic appearance of the gas supply accumulation unit. A gas supply accumulation unit 240 shown in FIG. 2 is a unit that is made by assembling the parts surrounded by the dotted line in FIG. 1.

As shown in FIG. 2, the gas supply accumulation unit 240 includes the above-described fluid controllers 231 to 238 and the passage blocks 241 to 249 which are connected to the respective fluid controllers 231 to 238. Passages are formed in these passage blocks 241 to 249. The respective fluid controllers 231 to 238 are connected to each other by these passages.

(Structural Example of Passage Block)

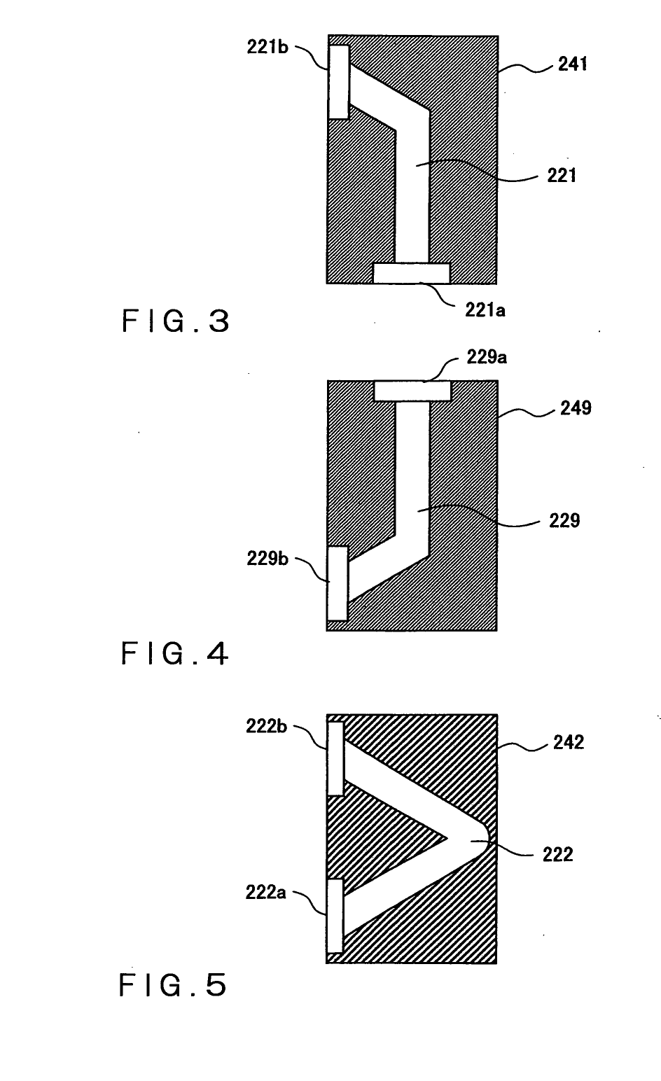

The respective passage blocks 241 to 249 are described with reference to the drawings. FIG. 3 is a sectional view of an example of an inner structure of the passage block 241 to be located on the most upstream side position. FIG. 4 is a sectional view of an example of an inner structure of the passage block 249 to be located on the most downstream side position. FIG. 5 is a sectional view of an example of an inner structure of each of the passage blocks 242 to 248 to be located on intermediate positions.

The passage block 241 to be located on the most upstream side position of the gas supply accumulation unit 240 shown in FIG. 2 includes a passage 221 to be connected to the gas supply source 210 shown in FIG. 1. As shown in FIG. 3, for example, the passage 221 is formed in the passage block 241. The gas supply source 210 is connected to one end 221a of the passage 221, and the hand valve 231 is connected to the other end 221b.

The passage block 249 to be located on the most downstream side position of the gas supply accumulation unit 240 shown in FIG. 2 includes a passage 229 to be connected to the nozzle 202 of the reaction tube 112 shown in FIG. 1. As shown in FIG. 4, for example, the passage 229 is formed in the passage block 249. The nozzle 202 is connected to one end 229a of the passage 229, and the gas filter (FE) 238 is connected to the other end 229b.

The respective passage blocks 242 to 248, which are located between the passage blocks 241 and 249, include passages 222 to 228 to which the respective fluid controllers 231 to 238 shown in FIG. 1 are connected. The passages 222 to 228 formed in the respective passage blocks 242 to 248 have the same shape. For example, as shown in FIG. 5, the passage 222 of a V-shape is formed in the passage block 242. The hand valve 231 is connected to one end 222a of the passage 222, and the pressure reducing valve (regulator) 232 is connected to the other end 222b.

In a case where the respective passage blocks 241 to 249 are made of a metal such as a stainless steel, similarly to a conventional piping, there arise problems in that, when a fluorinated corrosive gas (e.g., HF gas) supplied from the gas supply source 210 is circulated, the gas reacts with a metal constituting the passages 221 to 229 which are in contact with the gas so as to generate an undesired metal fluoride, and/or that the gas corrodes the metal constituting the passages 221 to 229 so that a metal component thereof (Fe, Cr, Ni, or the like) comes to be mixed in the corrosive gas. The metal contaminant, such as the metal fluoride and the metal component, together with the corrosive gas, penetrate the reaction tube 112 to generate particles on a wafer W, which results in a metal contamination.

In view of the above, in this embodiment, the respective passage blocks 241 to 249 are made of a nonmetallic carbon material. Thus, it is possible to prevent generation of a metal fluoride when a fluorinated corrosive gas is circulated through the passages 221 to 229 formed in the respective passage blocks 241 to 249. Simultaneously, mixture of a metal component can be prevented, whereby mixture of a metal contaminant into a wafer can be prevented as much as possible.

In addition, by making the respective passage blocks 241 to 249 themselves constituting the passages out of a nonmetallic carbon material, a degree of accumulation of the gas supply passage apparatuses can be made higher, while a strength of the parts constituting the passages can be made stronger, as compared with a case in which passages are formed of gas pipings.

As a carbon material for making the respective passage blocks 241 to 249, it is preferable to use a carbon sintered material such as a carbon sintered compact. Further, it is preferable that the carbon sintered compact is impregnated with a fluorocarbon resin such as Teflon (registered trademark) resin. A porous carbon sintered compact impregnated with a resin such as a fluorocarbon resin can improve a gas leaking property of the respective passage blocks 241 to 249.

Alternatively, as a carbon material other than the carbon sintered material, a hard carbon material (hard carbon film) such as amorphous carbon and diamond-like carbon (DLC) may be used to make the respective passage blocks 241 to 249. It is possible to combine the hard carbon material and the carbon sintered material with each other.

Further, it is possible to make the overall passage blocks 241 to 249 out of a carbon material, or to make only a wall part constituting each of the passages through which a corrosive gas passes. In this case, the wall part constituting each of the passages of the respective passage blocks 241 to 249 may be coated with diamond-like carbon (DLC) by a CVD method (chemical vapor deposition method), for example.

Furthermore, not only the passage blocks 241 to 249, but also the gas-contacting parts (i.e., the parts in contact with a gas) of the fluid controllers which are connected by these passage blocks, may be made of a carbon material. For example, surfaces of structural elements (e.g. a spring member) of the valves 231, 235, and 236 and the pressure reducing valve 232, and a surface of a structural element (e.g., a strain gage) of the manometer 233 may be coated with diamond-like carbon (DLC) by a CVD method. In this case, also in the fluid controllers, generation of a metal fluoride and mixture of a metal component can be prevented.

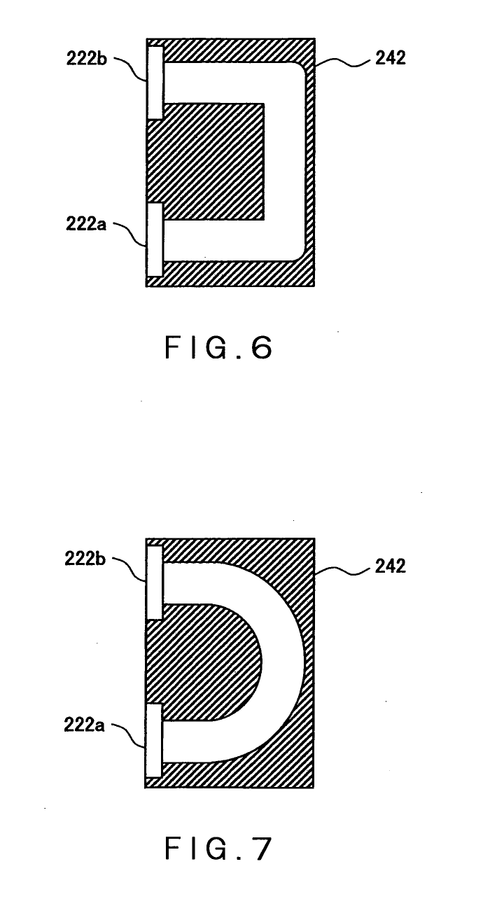

Moreover, the shape of the passages of the passage blocks 241 to 249 is not limited to the above-described one. For example, each of the passages formed in the passage blocks 242 to 248, which are located on the intermediate positions, may have an opened rectangular shape which is shown in FIG. 6, or may have a U-shape which is shown in FIG. 7. In addition, although the passage blocks 241 to 249 are structured by the plurality of blocks, the passage blocks 241 to 249 may be integrally structured. The passage of the passage block may be formed by drilling a carbon material such as a carbon sintered material. Alternatively, the passage of the passage block may be formed by sintering a carbon material with the use of a mold capable of providing a passage of a desired shape. When the passage block is made of a carbon material such as a carbon sintered material, it is easier to form the passage into a desired shape.

In the above embodiment, although the gas supply system 200 including the single gas supply accumulation unit 240 has been described, the gas supply system 200 is not limited thereto. For example, in a case where various gases are supplied into the reaction tube 112 connected to the processing part 110, it is possible to dispose the plurality of gas supply accumulation units for the respective gases. In this case, out of these gas supply accumulation units, only the passage blocks of the gas supply accumulation unit for supplying a corrosive gas may be made of a carbon material. Thus, it is sufficient to use a carbon material for only the gas supply accumulation unit which is required to prevent mixture of a metal contaminant into a wafer. Namely, only by modifying a part of the plurality of stainless-steel gas supply accumulation unit in an existing gas supply unit, mixture of a metal contaminant into a wafer can be prevented.

In the above embodiment, for example, the passages connecting the fluid controllers are structured by the gas supply accumulation unit, and the passage blocks are used as members for constituting the passages. However, not limited thereto, the members constituting the passages may be formed of gas pipings. In this case, it is possible to make the overall gas pipings out of a carbon material. Alternatively, inner walls of the gas pipings may be coated with a carbon material (e.g., a hard carbon material film).

Although the preferred embodiment of the present invention has been described with reference to the drawings, it goes without saying that the present invention is not limited thereto. It is apparent that, within a scope of the invention recited in the claims, various changes and modifications are obvious to those skilled in the art, and such changes and modifications should be within a technical scope of the present invention.

For example, in the above embodiment, the heat processing apparatus is taken as an example of a semiconductor manufacturing apparatus. However, not limited thereto, the present invention may be applied to various types of semiconductor manufacturing apparatuses as long as the semiconductor manufacturing apparatus processes a substrate by introducing thereinto a gas. For example, in addition to the heat processing apparatus, the present invention may be applied to, e.g., an etching apparatus and a film-deposition apparatus as a semiconductor manufacturing apparatus.

1. A gas supply system of a semiconductor manufacturing apparatus, for supplying a predetermined gas from a gas supply source to a processing part of the semiconductor manufacturing apparatus, the gas supply system comprising a gas supply passage apparatus that is connected to the gas supply source and the processing part,
wherein the gas supply passage apparatus includes: a plurality of fluid controllers; and a passage structuring member including a passage, the passage structuring member connecting the respective fluid controllers; and
the passage structuring member is made of a carbon material.

2. The gas supply system of a semiconductor manufacturing apparatus according to claim 1, wherein
the passage structuring member is formed of a passage block including a passage.

3. The gas supply system of a semiconductor manufacturing apparatus according to claim 1, wherein
the carbon material of the passage structuring member is formed of a carbon sintered material, a hard carbon material, or a combination thereof.

4. The gas supply system of a semiconductor manufacturing apparatus according to claim 3, wherein
the carbon sintered material is impregnated with a fluorocarbon resin.

5. The gas supply system of a semiconductor manufacturing apparatus according to claim 1, wherein
the plurality of fluid controllers include a valve, a pressure reducing valve, and a manometer.

6. The gas supply system of a semiconductor manufacturing apparatus according to claim 5, wherein
each of the fluid controllers has a gas-contacting part which is in contact with the gas, and the gas-contacting part is made of a carbon material.

7. A gas supply accumulation unit for supplying a predetermined corrosive gas to a processing part of a semiconductor manufacturing apparatus, the gas supply accumulation unit comprising:
a plurality of fluid controllers; and
a passage block including a passage, the passage block connecting the respective fluid controllers;
wherein the passage block is made of a carbon material.

8. The gas supply accumulation unit according to claim 7, wherein
the corrosive gas is formed of a fluorinated corrosive gas.

9. The gas supply accumulation unit according to claim 8, wherein
the corrosive gas is formed of an HF gas, an F₂ gas, a CIF₃ gas, or a mixture gas containing these gases.

10. The gas supply accumulation unit according to claim 7, wherein
the carbon material of the passage block is formed of a carbon sintered material impregnated with a fluorocarbon resin.
